(19) United States
(12) Patent Application Publication
(10) Pub. No.: US 2019/0006439 A1
(43) Pub. Date: Jan. 3, 2019

(54) DISPLAY PANEL, FABRICATION METHOD THEREOF, AND ELECTRONIC DEVICE

(71) Applicant: Lenovo (Beijing) Co., Ltd., Beijing (CN)

(72) Inventor: Jun Shi, Beijing (CN)

(21) Appl. No.: 15/941,359

(22) Filed: Mar. 30, 2018

(30) Foreign Application Priority Data
Jun. 30, 2017 (CN) 201710524424.1

(51) Int. Cl. H01L 27/32; H01L 51/52; H01L 51/00; G06K 9/00

(52) U.S. Cl. CPC H01L 27/3225; H01L 27/3246; H01L 51/525; H01L 2227/323; H01L 51/0096; G06K 9/0002; H01L 51/0024

(57) ABSTRACT

A display panel includes an upper glass substrate, a lower glass substrate, a supporting member, a thin film transistor, and a filling layer. The supporting member may be disposed between the upper glass substrate and the lower glass substrate. The thin film transistor may be disposed on a side of the lower glass substrate facing the upper glass substrate. The filling layer may be disposed between the upper glass substrate and the lower glass substrate. Further, the filling layer allows traverse of light and ultrasonic waves, and the filling layer is in a flow state or a solid state.

### CROSS-REFERENCES TO RELATED APPLICATION

This application claims priority to Chinese Patent Application No. 201710524424.1, filed on Jun. 30, 2017, the entire contents of which are hereby incorporated by reference.

### TECHNICAL FIELD

The present disclosure generally relates to the technical field of organic light-emitting (OLED) display and, more particularly, to a display panel, an electronic device, and a fabrication method of the display panel.

### BACKGROUND

Conventional glass-based organic light-emitting diode (hereinafter referred to as “G-OLED”) display panels often include: two glass substrates, thin film transistors disposed between the two glass substrates, and a light-emitting material. The two glass substrates may each have a thickness of around 0.2 mm-0.3 mm. A certain gap often exists between the two glass substrates, thus allowing the existence of a certain amount of gas.

The conventional G-OLED display panels work fine under most current situations. But as the users have a growing demand on higher screen-to-body ratio of display panels that possess a fingerprint collecting function, the integral design of display panels requires a fingerprint sensor to be under the screen, i.e., the fingerprint sensor needs to be placed under the display panel. One common fingerprint collecting solution is the ultrasonic fingerprint technique.

The principles of ultrasonic fingerprint collection is to utilize the capability of the sound wave with a frequency higher than 20 kHz in traversing materials, as well as the feature that different echoes are generated when different materials are applied. For example, when the ultrasonic wave arrives at the surface of different materials, the degree of absorption, transmission and reflection of the ultrasonic wave can be different. Thus, by utilizing the difference between the acoustic impedances of the skin and the air, the positions of the fingerprint ridges and furrows may be differentiated, such that the objective of fingerprint identification can be achieved.

However, during the propagation process of the ultrasonic wave, to avoid the occurrence of total reflection, the difference between the acoustic impedances of two adjacent media cannot be too large. For example, the difference often needs to be less than or equal to 20 times. The acoustic impedance of a medium refers to the resistance that needs to be overcome in order to displace the medium, which can be expressed as the product of the density of the medium and the sound velocity.

However, the difference in the acoustic impedance between gas and solid (or liquid) is greater than 20 times. Thus, if there is any lift in the propagation path from the surface of the ultrasonic fingerprint to the surface of the finger, malfunction of the ultrasonic fingerprint collection occurs. In other words, the existing G-OLED cannot apply the under-display ultrasonic fingerprint technique.

### BRIEF SUMMARY OF THE DISCLOSURE

One aspect of the present disclosure provides a display panel. The display panel includes an upper glass substrate, a lower glass substrate, a supporting member, a thin film transistor, and a filling layer. The supporting member may be disposed between the upper glass substrate and the lower glass substrate. The thin film transistor may be disposed on a side of the lower glass substrate facing the upper glass substrate. The filling layer may be disposed between the upper glass substrate and the lower glass substrate. Further, the filling layer allows traverse of light and ultrasonic waves, and the filling layer is in a flow state or a solid state.

Another aspect of the present disclosure provides an electronic device. The electronic device includes a display panel and an ultrasonic fingerprint sensor. The display panel includes an upper glass substrate, a lower glass substrate, and a filling layer. The filling layer is disposed between the upper glass substrate and the lower glass substrate, and the filling layer is in a flow state or a solid state. The ultrasonic waves emitted by the ultrasonic fingerprint identifier traverses the filling layer.

Another aspect of the present disclosure provides a method for fabricating a display panel. The method includes: disposing a thin film transistor on a lower glass substrate; disposing a supporting member on the lower glass substrate; disposing a filling layer on an upper glass substrate based on a pre-configured distance between the upper glass substrate and the lower glass substrate after cell-assembly; and assembling the upper glass substrate and the lower glass substrate with a side of the upper glass substrate disposed with the filling layer facing a side of the lower glass substrate disposed with the thin film transistor, such that the upper glass substrate contacts the supporting member.

Other aspects of the present disclosure can be understood by those skilled in the art in light of the description, the claims, and the drawings of the present disclosure.

### BRIEF DESCRIPTION OF THE DRAWINGS

In order to more clearly illustrate technical solutions in embodiments of the present disclosure, drawings for describing the embodiments are briefly introduced below. Obviously, the drawings described hereinafter are only some embodiments of the present disclosure, and it is possible for those ordinarily skilled in the art to derive other drawings from such drawings without creative effort.

FIG. 1 illustrates a structural schematic view of an example of a display panel in accordance with some embodiments of the present disclosure;

FIG. 2 illustrates a schematic view of an example of an intermediate structure during preparation of the display panel;

FIG. 3 illustrates a schematic view of an example of another intermediate structure during preparation of the display panel;

FIG. 4 illustrates a schematic view of an example of another intermediate structure during preparation of the display panel;

FIG. 5 illustrates a schematic view of an example of another intermediate structure during preparation of the display panel; and

FIG. 6 illustrates a schematic view of an example of another intermediate structure during preparation of the display panel.

FIG. 7 schematically shows an example electronic device consistent with the disclosure.

In the accompanying drawings:

1—upper glass substrate; 2—lower glass substrate; 3—filling layer; 4—supporting member; 5—thin film transistor; 6—spacer; 7—organic material

### DETAILED DESCRIPTION

Various solutions and features of the present disclosure will be described hereinafter with reference to the accompanying drawings. It should be understood that, various modifications may be made to the embodiments described below. Thus, the specification shall not be construed as limiting, but is to provide examples of the disclosed embodiments. Further, in the specification, descriptions of well-known structures and technologies are omitted to avoid obscuring concepts of the present disclosure.

The terminology used herein is for the purpose of describing specific embodiments and is not intended to be limiting of the present disclosure. As used herein, the singular forms “a,” “an,” and “the” are intended to include the plural forms as well, unless the context clearly indicates otherwise. Further, the terms “include,” “including,” “comprise,” and “comprising” specify the present of the stated features, steps, operations, components and/or portions thereof, but do not exclude the possibility of the existence or adding one or more other features, steps, operations, components, and/or portions thereof.

As used herein, the term “and/or” includes any and all combinations of one or more of the associated listed items. Expression such as “at least one of” when preceding a list of elements may modify the entire list of elements and may not modify the individual elements of the list.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

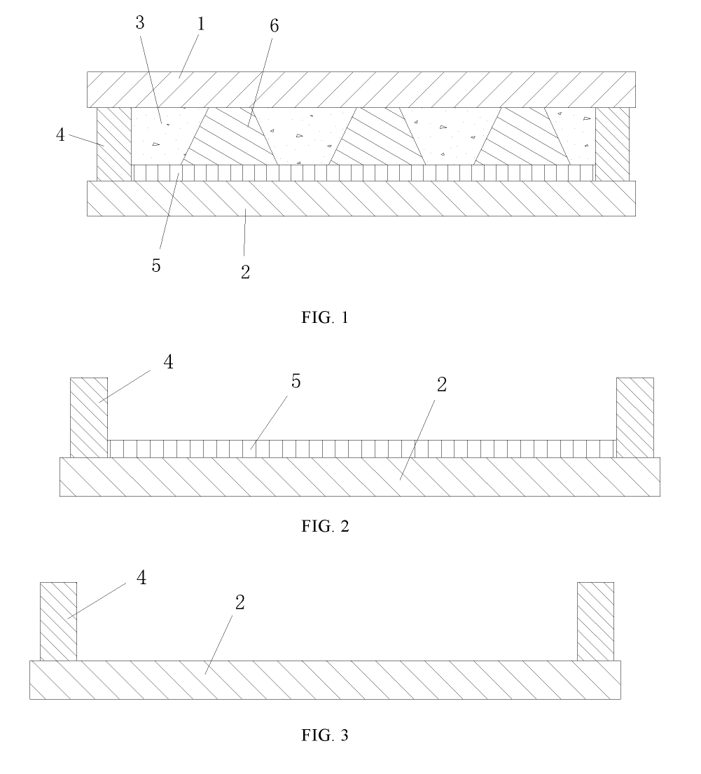

The present disclosure provides a display panel for realizing under-display ultrasonic fingerprint collection. FIG. 1 illustrates a structural schematic view of an example of a display panel in accordance with some embodiments of the present disclosure. As shown in FIG. 1, the display panel includes an upper glass substrate 1, a lower glass substrate 2, a filling layer 3, a plurality of supporting members 4, and a thin film transistor 5. In some embodiments, as shown in FIG. 1, the display panel further includes a plurality of spacers 6.

The filling layer 3 may be, for example, made of an organic material 7 (shown in FIG. 5) and may be in a flow state or a solid state. Further, the filling layer 3 is sandwiched between the upper glass substrate 1 and the lower glass substrate 2 to allow light and ultrasonic waves to pass through. By introducing the filling layer 3, no air interlayer may exist between the upper glass substrate 1 and the lower glass substrate 2, thus preventing the phenomenon of total reflection from occurring when the ultrasonic waves traverse the upper glass substrate 1 or the lower glass substrate 2. Thus, the disclosed display panel may be applied to technical solutions in which the fingerprint identifier is disposed below the display panel. That is, the disclosed display panel may be applied to electronic devices to achieve a maximal screen-to-body ratio.

In some embodiments, the acoustic impedance of the material forming the filling layer 3 is within a certain range to ensure that the filling layer 3 does not impact the propagation of the ultrasonic waves. In some embodiments, the ratio between the acoustic impedance of the material forming the upper glass substrate 1 or the lower glass substrate 2 and the acoustic impedance of the material forming the filling layer 3 may be within a certain range or smaller than a certain value. For example, the ratio may be equal to or smaller than about 20, i.e., the acoustic impedance of the material forming the filling layer 3 may be equal to or larger than about 1/20 of the acoustic impedance of the material forming the upper glass substrate 1 or the lower glass substrate 2.

In some embodiments, the filling layer 3 may be a solid-state organic material layer. The solid-state organic material layer may be formed by solidification of an organic material 7 in a flow state between the upper glass substrate 1 and the lower glass substrate 2 through UV radiation or heating. In one example, the filling layer 3 may be made of polyimide, and may be solidified between the upper glass substrate 1 and the lower glass substrate 2 through UV radiation. That is, the filling layer 3 may be made of a solidified polyimide. In other examples, the filling layer 3 may be made of other organic materials, as long as the organic material 7 selected for forming the filling layer 3 has a relatively good transmissivity, does not react with other materials of the display panel, and remains to be stable in the display panel.

The supporting members 4 may be disposed on the lower glass substrate 2, with the tops of the supporting members 4 in contact with the upper glass substrate 1. The supporting members 4 may be configured to support and secure the relative positions of the upper glass substrate 1 and the lower glass substrate 2. For example, each supporting member 4 may include a columnar member made of glass glue.

The thin film transistor 5 may be disposed on the lower glass substrate 2. Further, because the light-emitting material of the thin film transistor 5 is fragile and the upper glass substrate 1 has certain rigidity, the plurality of spacers 6 may be disposed on the thin film transistor 5 to avoid damages to the light-emitting material caused by the upper glass substrate 1 getting in contact with the thin film transistor 5 directly. The lower side of the upper glass substrate 1 may be in contact with the plurality of spacers 6, thus allowing the contact between the light-emitting material and the upper glass substrate to be a flexible contact (e.g., indirect contact). Accordingly, the light-emitting material of the thin film transistor 5 is prevented from being damaged.

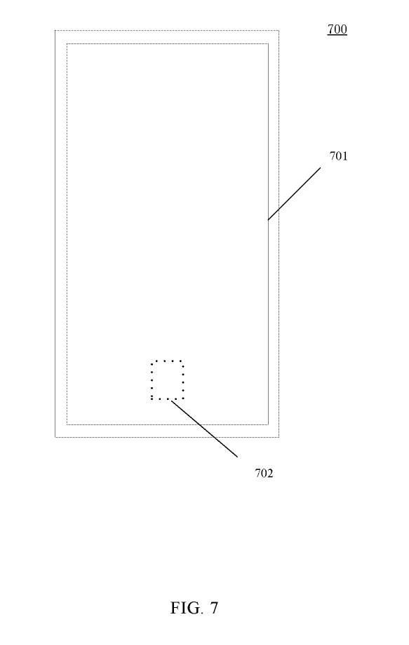

The present disclosure further provides an electronic device. FIG. 7 schematically shows an example electronic device 700 consistent with the disclosure. The electronic device 700 includes a display panel 701, which can be any display panel consistent with the disclosure, such as the example display panel shown in FIG. 1 and described above. Referring to both FIGS. 1 and 7, the display panel 701 includes an upper glass substrate 1, a lower glass substrate 2, and a filling layer 3 sandwiched between the upper glass substrate 1 and the lower glass substrate 2. The filling layer 3 may be in a flow state or a solid state. The electronic device 700 further includes an ultrasonic fingerprint identifier 702, and the ultrasonic fingerprint identifier 702 may be disposed below the display panel 701. For example, the ultrasonic fingerprint identifier may be a fingerprint sensor. The ultrasonic fingerprint identifier may be configured to emit ultrasonic waves, and the ultrasonic waves emitted by the ultrasonic fingerprint identifier may traverse the filling layer 3. Further, ultrasonic waves reflected by human hand or finger may also traverse the filling layer 3.

By configuring the ultrasonic fingerprint identifier below the display panel, a first surface (i.e., upper surface) of the electronic device may have a maximal integral display screen of the display panel. That is, the screen-to-body ratio may be maximized. Further, the ultrasonic waves configured to detect or collect the fingerprint may come from the area where the display screen of the display panel is. In other words, the display panel of the disclosed electronic device may support the function of high-precision fingerprint identification, and the user may perform fingerprint identification through the display panel.

Further, the acoustic impedance of the material forming the filling layer 3 may have a certain value that does not impact the ultrasonic waves. Thus, the filling layer 3 may not affect the propagation of the ultrasonic waves. The filling layer 3 may be, for example, formed by solidification of polyimide through UV radiation.

In some embodiments, the display panel of the disclosed electronic device may further include a plurality of supporting members 4, a thin film transistor 5, and a plurality of spacers 6. The supporting members 4 may be disposed on the lower glass substrate 2, with the tops thereof in contact with the upper glass substrate 1. Further, the supporting members 4 may be configured to support and secure the relative positions of the upper glass substrate 1 and the lower glass substrate 2. For example, a supporting member 4 may be a columnar member made of glass glue.

The thin film transistor 5 may be disposed on the lower glass substrate 2. The plurality of spacers 6 may be disposed on the thin film transistor 5 to avoid damages to the light-emitting material of the thin film transistor 5 caused by the upper glass substrate 1 getting in contact with the thin film transistor 5 directly. That is, by configuration of the plurality of spacers 6, the contact between the light-emitting material of the thin film transistor 5 and the upper glass substrate is flexible contact (e.g., indirect contact).

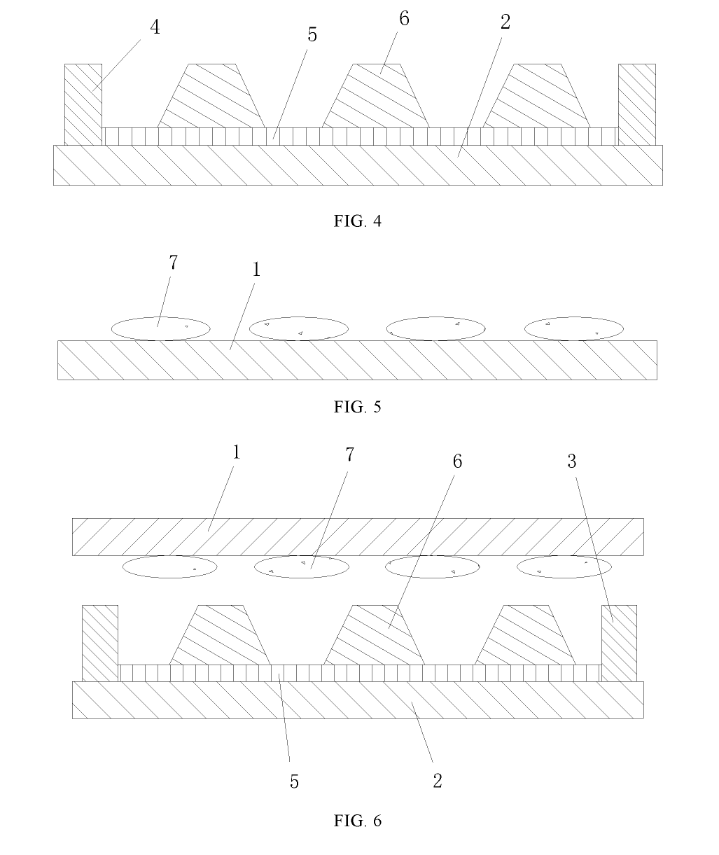

The present disclosure further provides a fabrication method of the display panel. FIGS. 2-6 each illustrates a schematic view of an example of an intermediate structure during fabrication of a display panel in accordance with some embodiments of the present disclosure. As shown in FIGS. 2-6, the method may include: disposing a thin film transistor 5 on a lower glass substrate 2; disposing a supporting member 4 on the lower glass substrate 2; disposing a filling layer 3 on an upper glass substrate 1 based on a pre-configured distance between the upper glass substrate 1 and the lower glass substrate 2 after cell assembly, where the filing layer 3 is in a flow state or a solid state.

The fabrication method further includes: cell-assembling a side of the upper glass substrate 1 that is disposed with the filling layer 3 to a side of the lower glass substrate 2 disposed with the thin film transistor 5, and enabling the upper glass substrate 1 to contact the supporting members 4. That is, the upper glass substrate 1 and the lower glass substrate 2 are supported and secured through the supporting members 4. The cell-assembling process may be fulfilled in a vacuum environment.

Further, disposing a filling layer 3 on the upper glass substrate 1 may include disposing an organic material 7 in a flow state on the upper glass substrate 1 through drop-filling or coating. In some embodiments, the approach of “One Drop Filling (ODF)” may be applied to drop-filling a certain amount of liquid organic material between the two glass substrates (i.e., the upper and lower glass substrates). For example, referring to FIG. 5, a certain amount of organic material 7 may be disposed on one side of the upper glass substrate 1 through ODF, and the upper glass substrate 1 may be assembled with the lower glass substrate 2 with the side of the upper glass substrate 1 disposed with the organic material 7 facing towards supporting members 4 on the lower substrate glass 2, as shown in FIG. 6. The density of the organic material 7 may be close to the density of other solid-state materials of the display panel, such that the weight of the display panel does not change significantly.

In some other embodiments, a soft layer of organic material 7 may be coated on the upper glass substrate 1, and the organic material 7 may automatically fill the gap between the two glass substrates during the subsequent cell-assembling process of the glass substrates. The organic material 7 may be polyimide, or other organic materials, as long as the organic material 7 has relatively good transmissivity, does not react with other materials of the display panel, and remains stable in the display panel.

Further, after the above-described cell-assembling, the method further includes: solidifying the filling layer 3 through UV radiation or heating, thereby reducing the difference between the acoustic impedance of the filling layer 3 and the acoustic impedance of the upper glass substrate 1 or the lower glass substrate 2, and improving the accuracy of the ultrasonic fingerprint identification. For example, the UV radiation may be applied to solidify polyimide to form the filling layer 3.

In some embodiments, after disposing the supporting member 4 and before disposing the filling layer 3, the method further includes: disposing a plurality of spacers 6 on the thin film transistor 5. Thus, when the upper glass substrate 1 is cell-assembled with the lower glass substrate 2, one side of the upper glass substrate 1 may contact with the spacers 6, thereby preventing the thin film transistor 5 from being damaged.

As such, a display panel is fabricated suitable for ultrasonic fingerprint identification. The fabricated display panel may be applied to electronic devices to achieve a maximal screen-to-body ratio.

As such, the disclosed electronic device may realize under-display fingerprint detection or identification. The first surface of the electronic device may have the maximal screen-to-body ratio. The filling layer of the display panel may be in a flow state or a solid state. The filling layer may generate no impact on the ultrasonic fingerprint detection. That is, disturbance on the ultrasonic waves caused by the filling material being a gas can be avoided, thus improving the accuracy of the ultrasonic fingerprint detection.

The foregoing embodiments are merely examples embodiments of the present disclosure, and are not intended to limit the present disclosure. The scope of the present invention is defined by the appended claims. Without departing from the spirit and scope of the present disclosure, those skilled in the relevant art can make various modifications or equivalent replacements to the present disclosure. Such modifications or equivalent replacements shall all fall within the scope of the present disclosure.

What is claimed is:

1. A display panel comprising:
an upper glass substrate;
a lower glass substrate;
a supporting member disposed between the upper glass substrate and the lower glass substrate;
a thin film transistor disposed on a side of the lower glass substrate facing the upper glass substrate; and
a filling layer disposed between the upper glass substrate and the lower glass substrate, wherein the filling layer allows traverse of light and ultrasonic waves, and the filling layer is in a flow state or a solid state.

2. The display panel according to claim 1, wherein:
a ratio between an acoustic impedance of a material forming the upper glass substrate or the lower glass substrate and an acoustic impedance of a material forming the filling layer is equal to or smaller than a preset value to reduce an impact of the filling layer on the ultrasonic waves.

3. The display panel according to claim 2, wherein:
the filling layer includes a solid-state organic material layer.

4. The display panel according to claim 1, wherein:
the supporting member includes a columnar made of glass glue.

5. An electronic device comprising:
a display panel including:
an upper glass substrate;
a lower glass substrate; and
a filling layer disposed between the upper glass substrate and the lower glass substrate, wherein the filling layer is in a flow state or a solid state; and
an ultrasonic fingerprint sensor, wherein ultrasonic waves emitted by the ultrasonic fingerprint identifier traverses the filling layer.

6. The electronic device according to claim 5, wherein:
a ratio between an acoustic impedance of a material forming the upper glass substrate or the lower glass substrate and an acoustic impedance of a material forming the filling layer is equal to or smaller than a preset value to reduce an impact of the filling layer on the ultrasonic waves.

7. The electronic device according to claim 5, wherein:
a surface of the electronic device maximally exposes the display panel, and
the ultrasonic fingerprint sensor is disposed at a screen region of the display panel.

8. A method for fabricating a display panel comprising:
disposing a thin film transistor on a lower glass substrate;
disposing a supporting member on the lower glass substrate;
disposing a filling layer on an upper glass substrate based on a pre-configured distance between the upper glass substrate and the lower glass substrate after cell-assembly; and
assembling the upper glass substrate and the lower glass substrate with a side of the upper glass substrate disposed with the filling layer facing a side of the lower glass substrate disposed with the thin film transistor, such that the upper glass substrate contacts the supporting member.

9. The method according to claim 8, wherein:
disposing the filling layer on the upper glass substrate includes disposing an organic material in a flow state on the upper glass substrate through drop filling or coating.

10. The method according to claim 8, further comprising:
solidifying the filling layer through heating or UV radiation.
